(19) United States
(12) Patent Application Publication
(10) Pub. No.: US 2021/0313549 A1
(43) Pub. Date: Oct. 7, 2021

(54) DISPLAY PANEL AND METHOD FOR MANUFACTURING THE SAME, AND DISPLAY DEVICE

(71) Applicant: BOE Technology Group Co., Ltd., Beijing (CN)

(72) Inventors: Junbo Wei, Beijing (CN); Kuanta Huang, Beijing (CN); Pengcheng Lu, Beijing (CN); Shengji Yang, Beijing (CN); Xiaochuan Chen, Beijing (CN)

(73) Assignee: BOE Technology Group Co., Ltd., Beijing (CN)

(21) Appl. No.: 17/266,196

(22) PCT Filed: Jul. 2, 2020
(86) PCT No.: PCT/CN2020/099890

§ 371 Date: Feb. 5, 2021

(30) Foreign Application Priority Data
Jul. 2, 2019 (CN) 201910591529.8

(51) Int. Cl. H01L 51/56; H01L 51/52; H01L 27/32

(52) U.S. Cl. CPC H01L 51/56; H01L 51/5253; H01L 51/524; H01L 2227/323; H01L 27/3276; H01L 27/3223

(57) ABSTRACT

A display panel is provided and includes: a first substrate; an electrode arranged on the first substrate; an organic light-emitting layer arranged on a side of the electrode away from the first substrate; a photo-curable adhesive layer covering the organic light-emitting layer; a second substrate arranged on a side of the photo-curable adhesive layer away from the first substrate; and a light shielding structure located on a side of the second substrate facing the first substrate and located in an edge area which is located a side of the second substrate facing the electrode; wherein an orthographic projection of the light shielding structure on the first substrate does not overlap the orthographic projection of the organic light-emitting layer on the first substrate. A display device and a method for manufacturing a display panel are further provided.

### CROSS-REFERENCE TO RELATED APPLICATION(S)

This application is a Section 371 National Stage Application of International Application No. PCT/CN2020/099890, filed on Jul. 2, 2020, entitled “DISPLAY PANEL AND METHOD FOR MANUFACTURING THE SAME, AND DISPLAY DEVICE”, which claims priority to Chinese Patent Application No. 2019105915298, filed on Jul. 2, 2019, which is incorporated herein by reference in its entirety.

### TECHNICAL FIELD

The present disclosure relates to a field of display technology, and in particular to a display panel and a method for manufacturing the same, and a display device.

### BACKGROUND

Organic light-emitting device is a new type of self-luminous display device, which has characteristics of a low driving voltage, a high luminous efficiency, a short response time, a high definition, and a high contrast. The organic light-emitting device is manufactured by mature processes, which may achieve self-luminescence through characteristics of organic materials, and have an advantage of lightweight. The organic light-emitting device is widely used in TV display panels, mobile phone display panels, near-eye displays, virtual reality, and augmented reality. In a different application environment, the organic light-emitting device may have a different service life.

### SUMMARY

In one aspect, the present disclosure provides a display panel, including: a first substrate; an electrode arranged on the first substrate; an organic light-emitting layer arranged on a side of the electrode away from the first substrate, wherein an orthographic projection of a cross section of the organic light-emitting layer on the first substrate does not overlap an orthographic projection of a cross section of the electrode on the first substrate; a photo-curable adhesive layer covering the organic light-emitting layer; a second substrate arranged on a side of the photo-curable adhesive layer away from the first substrate; and a light shielding structure located on a side of the second substrate facing the first substrate and located in an edge area which is located on a side of the second substrate facing the electrode; wherein an orthographic projection of a cross section of the light shielding structure on the first substrate does not overlap the orthographic projection of the cross section of the organic light-emitting layer on the first substrate.

In some embodiments, an orthographic projection of a cross section of the photo-curable adhesive layer on the first substrate covers the orthographic projection of the cross section of the organic light-emitting layer on the first substrate; and an orthographic projection of a cross section of the second substrate on the first substrate completely overlaps the orthographic projection of the cross section of the photo-curable adhesive layer on the first substrate.

In some embodiments, each of orthographic projections of cross sections of the light shielding structure, the second substrate, and the photo-curable adhesive layer on the first substrate does not overlap the orthographic projection of the cross section of the electrode on the first substrate; and a sidewall of the light shielding structure close to the electrode coincides with a sidewall of the photo-curable adhesive layer close to the electrode.

In some embodiments, the orthographic projection of the cross section of the light shielding structure on the first substrate is located between the orthographic projection of the cross section of the electrode on the first substrate and the orthographic projection of the cross section of the organic light-emitting layer on the first substrate.

In some embodiments, the photo-curable adhesive layer is made of an epoxy acrylic resin material.

In another aspect, the present disclosure provides a display device, including the display panel described above.

In yet another aspect, the present disclosure provides a method for manufacturing a display panel, including: providing a first substrate, and arranging an electrode and an organic light-emitting layer on the first substrate; coating the electrode and the organic light-emitting layer with a photo-curable adhesive, and covering the first substrate with the photo-curable adhesive; providing a mother substrate for a second substrate, and arranging a light shielding layer on the mother substrate; arranging the mother substrate with the light shielding layer on the photo-curable adhesive, with the light shielding layer facing the first substrate, wherein the light shielding layer is configured to shield light irradiated on the electrode, and an orthographic projection of a cross section of the light shielding layer on the first substrate does not overlap an orthographic projection of a cross section of the organic light-emitting layer on the first substrate; performing a curing treatment on the photo-curable adhesive to form a photo-curable adhesive material layer, wherein the photo-curable adhesive material layer includes an uncured portion; cutting at a predetermined cutting position to cut off a portion of each of the mother substrate and the light shielding layer, so as to form the second substrate and a light shielding structure, respectively; peeling off the uncured portion of the photo-curable adhesive material layer to expose the electrode, wherein a remaining portion of the photo-curable adhesive material layer forms a photo-curable adhesive layer.

In some embodiments, the performing a curing treatment on the photo-curable adhesive includes performing an ultraviolet curing treatment on the photo-curable adhesive.

In some embodiments, the providing a light shielding layer on the mother substrate includes depositing the light shielding layer on the mother substrate by a deposition process.

In some embodiments, the light shielding layer is made of aluminum or titanium.

In some embodiments, the orthographic projection of the cross section of the light shielding layer on the first substrate covers an orthographic projection of a cross section of the electrode on the first substrate.

In some embodiments, an orthographic projection of a sidewall of the second substrate away from the organic light-emitting layer on the first substrate coincides with an orthographic projection of a sidewall of the light shielding layer away from the organic light-emitting layer on the first substrate in a cross-sectional direction of the second substrate.

In some embodiments, the cutting at a predetermined cutting position includes cutting between the electrode and the organic light-emitting layer, so that a distance between an orthographic projection of a cross section of the electrode on the first substrate and an orthographic projection of a cross section of the photo-curable adhesive layer on the first substrate is greater than 500 microns.

### BRIEF DESCRIPTION OF THE DRAWINGS

By reading the detailed description of the embodiments below, various other advantages and benefits will become clear to those ordinary skilled in the art. The drawings are only used for the purpose of showing the embodiments, and are not considered as a limitation to the embodiments of the present disclosure. Throughout the drawings, the same reference symbols are used to denote the same components.

FIG. 1A shows a schematic diagram of a simple structure of a display panel according to an embodiment of the present disclosure.

FIG. 1B shows a schematic structural diagram of a display panel according to an embodiment of the present disclosure.

FIG. 2 shows a schematic structural diagram of another display panel according to an embodiment of the present disclosure.

FIG. 3 shows a flowchart of a method for manufacturing a display panel according to an embodiment of the present disclosure.

FIG. 4 to FIG. 6 show schematic structural diagrams of a display panel in different stages of a manufacturing process according to an embodiment of the present disclosure.

### DETAILED DESCRIPTION OF EMBODIMENTS

Hereinafter, exemplary embodiments of the present disclosure will be described in more detail with reference to the drawings. Although the exemplary embodiments of the present disclosure are shown in the drawings, it should be understood that the present disclosure may be implemented in various forms and should not be limited by the embodiments described herein. On the contrary, these embodiments are provided to enable a more thorough understanding of the present disclosure and to fully convey the scope of the present disclosure to those skilled in the art.

Those skilled in the art may understand that unless specifically stated, the singular forms “a”, “an”, “said” and “the” used herein may also include the plural forms. It should be further understood that the expression “comprising” or “including” used in the specification of the present disclosure refers to the presence of the described features, integers, steps, operations, elements and/or components, but does not exclude the presence or addition of one or more other features, integers, steps, operations, elements, components, and/or groups thereof.

Those skilled in the art may understand that unless otherwise defined, all terms (including technical terms and scientific terms) used herein have the same meaning as those generally understood by those ordinary skilled in the art to which this application belongs. It should also be understood that terms such as those defined in a general dictionary should be understood to have a meaning consistent with the meaning in the context of the related art, and unless specifically defined as here, it would not be interpreted in an idealized or overly formal sense.

Technical solutions of the embodiments of the present disclosure will be described in detail below with reference to the drawings.

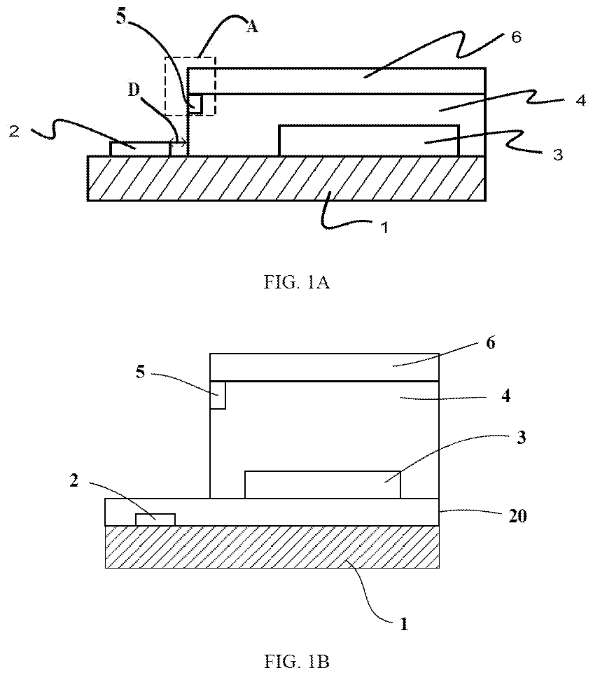

In a first aspect, an embodiment of the present disclosure provides a display panel, as shown in FIG. 1A, including: a first substrate 1; an electrode 2 arranged on the first substrate 1; an organic light-emitting layer 3 arranged on a side of the electrode 2 away from the first substrate 1, where an orthographic projection of the organic light-emitting layer 3 on the first substrate 1 is spaced apart from an orthographic projection of the electrode 2 on the first substrate 1, and as shown in FIG. 1B, an insulating layer 20 is further provided on the electrode 2; a photo-curable adhesive layer 4 arranged on the organic light-emitting layer 3; a second substrate 6 arranged on a side of the photo-curable adhesive layer 4 away from the first substrate 1; and a light shielding structure 5 arranged on a side of the second substrate 6 facing the first substrate 1 and located in an edge area A which is located on a side of the second substrate 6 facing the electrode 2. An orthographic projection of the light shielding structure 5 on the first substrate 1 does not overlap the orthographic projection of the organic light-emitting layer 3 on the first substrate 1. The arrangement of the electrode 2 and the organic light-emitting layer 3 is similar to that in the related art, which will not be repeated here.

In a display panel provided by an embodiment of the present disclosure, a production of the organic light-emitting layer may be achieved by using the photo-curable adhesive layer 4. The usage of the photo-curable adhesive layer may increase an area of a curable area, so as to improve a production effect, improve resistance to water and oxygen, and ensure a sufficient mechanical strength, thereby extending a service life of the organic light-emitting device including the electrode and the organic light-emitting layer. Moreover, the light shielding layer 51 provided on the second substrate may shield the electrode 2 from light during the manufacturing process without using additional shielding components. The manufacturing structure is simpler to expose the electrode 2, so that the electrode may be coupled with other electrical components without damaging the manufacturing process, thereby enhancing market competitiveness.

For example, continuing to refer to FIG. 1A, an orthographic projection of the photo-curable adhesive layer 4 on the first substrate 1 covers the orthographic projection of the organic light-emitting layer 3 on the first substrate 1. An orthographic projection of the second substrate 6 on the first substrate 1 completely overlaps the orthographic projection of the photo-curable adhesive layer 4 on the first substrate 1. Since the orthographic projection of the photo-curable adhesive layer 4 on the first substrate 1 is larger than the orthographic projection of the organic light-emitting layer 3 on the first substrate 1, it is ensured that the photo-curable adhesive layer 4 completely encapsulates the organic light-emitting layer 3.

For example, as shown in FIG. 1A, a sidewall of the light shielding structure 5 close to the electrode 2 coincides with a sidewall of the photo-curable adhesive layer 4 close to the electrode 2 in a cross-sectional direction of the second substrate 6, so that an overall structure of the display panel is more uniform, which obtains a more effective production effect.

In some embodiments, each of orthographic projections of the light shielding structure 5, the second substrate 6 and the photo-curable adhesive layer 4 on the first substrate 1 does not overlap the orthographic projection of the electrode 2 on the first substrate 1.

For example, in this embodiment, the photo-curable adhesive layer 4 may be made of an epoxy acrylic resin. However, for those skilled in the art, other suitable types of materials may also be selected.

For example, in this embodiment, the first substrate 1 is a thin film transistor substrate or a silicon substrate. The second substrate 6 is a metal substrate or a glass substrate. However, for those skilled in the art, other suitable types of first substrate I and second substrate 6 may also be selected.

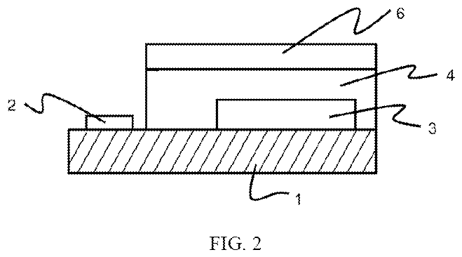

Based on the same concept, in a second aspect, an embodiment of the present disclosure provides a display panel, as shown in FIG. 2, including: a first substrate 1; an electrode 2 arranged on the first substrate 1; an organic light-emitting layer 3 arranged on a side of the electrode 2 away from the first substrate 1; a photo-curable adhesive layer 4 covering the organic light-emitting layer 3; and a second substrate 6. The arrangement of the electrode 2 and the organic light-emitting layer 3 is similar to that in the related art, which will not be repeated here.

In a display panel provided by an embodiment of the present disclosure, a production of the organic light-emitting layer may be completed by using the photo-curable adhesive layer 4. The usage of the photo-curable adhesive layer may increase an area of a curable area, so as to improve a production effect, improve resistance to water and oxygen, and ensure a sufficient mechanical strength, thereby extending a service life of the organic light-emitting device including the electrode and the organic light-emitting layer. The electrode 2 is exposed, so that the electrode may be coupled with other electrical components without affecting the manufacturing process, thereby enhancing market competitiveness.

For example, the orthographic projection of the photo-curable adhesive layer 4 on the first substrate 1 covers the orthographic projection of the organic light-emitting layer 3 on the first substrate 1, so that the photo-curable adhesive layer 4 may completely envelop the organic light-emitting layer 3, which obtains a more effective production effect. Furthermore, the orthographic projection of the second substrate 6 on the first substrate 1 completely overlaps the orthographic projection of the photo-curable adhesive layer 4 on the first substrate 1, which further improves the production effect.

Based on the same concept, in a third aspect, an embodiment of the present disclosure provides a display device, including the display panel described in the first aspect or the display panel described in the second aspect. Since the display device of the third aspect includes the display panel of the first aspect or the display panel of the second aspect, the display device has the same beneficial effects as the display panel. Therefore, the beneficial effects of the display device of the third aspect will not be repeated here.

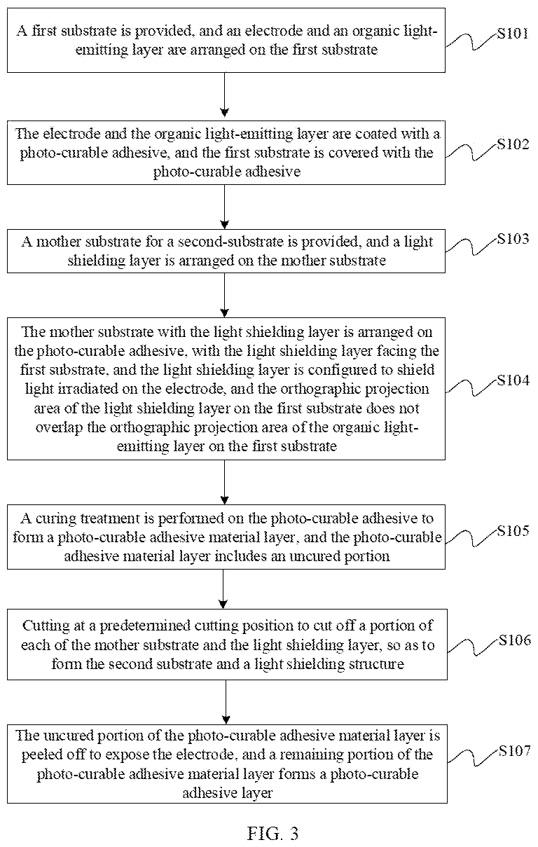

Based on the same concept, in a fourth aspect, an embodiment of the present disclosure provides a method for manufacturing a display panel. As shown in FIG. 3, the method includes the following steps.

S101: a first substrate is provided, and an electrode and an organic light-emitting layer are arranged on the first substrate.

S102: the electrode and the organic light-emitting layer are coated with a photo-curable adhesive, and the first substrate is covered with the photo-curable adhesive.

S103: a mother substrate for a second-substrate is provided, and a light shielding layer is arranged on the mother substrate.

S104: the mother substrate with the light shielding layer is arranged on the photo-curable adhesive, with the light shielding layer facing the first substrate, and the light shielding layer is configured to shield light irradiated on the electrode, and the orthographic projection of the light shielding layer on the first substrate does not overlap the orthographic projection of the organic light-emitting layer on the first substrate.

S105: a curing treatment is performed on the photo-curable adhesive to form a photo-curable adhesive material layer, and the photo-curable adhesive material layer includes an uncured portion.

S106: cutting at a predetermined cutting position to cut off a portion of each of the mother substrate and the light shielding layer, so as to form the second substrate and a light shielding structure, respectively.

S107: the uncured portion of the photo-curable adhesive material layer is peeled off to expose the electrode, and a remaining portion of the photo-curable adhesive material layer forms a photo-curable adhesive layer.

In a method for manufacturing the display panel provided by the present disclosure, the light shielding layer provided on the mother substrate for the second substrate may shield the electrode 2 during the manufacturing process without using additional shielding components, and thus the process for manufacturing the display panel may be simplified. Moreover, the production may be completed by using one type of photo-curable adhesive, so that in the curing process, the photo-curable adhesive material layer used may increase an area of the curable area, so as to improve the production effect, improve resistance to water and oxygen, and ensure a sufficient mechanical strength, thereby extending a service life of the organic light-emitting device. In addition, the electrode included in the organic light-emitting device is exposed, so that the electrode may be coupled to other electrical components without affecting the manufacturing process, which simplifies all the manufacturing steps, greatly improves a manufacturing efficiency, and enhances the market competitiveness.

In some embodiments, the providing a light shielding layer on the mother substrate includes depositing the light shielding layer on the mother substrate by a deposition process. A pattern of the light shielding layer may be formed by processes such as an exposure process and a development process.

In some embodiments, the light shielding layer is made of aluminum or titanium.

In some embodiments, the cutting at a predetermined cutting position includes cutting between the electrode and the organic light-emitting layer, so that a distance D between the electrode and the photo-curable adhesive layer is greater than 500 microns.

For example, the orthographic projection of the light shielding layer 51 on the first substrate 1 covers the orthographic projection of the electrode 2 on the first substrate 1. Therefore, when ultraviolet (UV) is used to cure the photo-curable adhesive, the light shielding layer 51 may block the UV, so that the UV may not irradiate the electrode 2 and the photo-curable adhesive material layer 41 on the electrode 2, which may prevent the UV from damaging the electrode 2. It may also prevent the photo-curable adhesive material layer 41 on the electrode 2 from curing, so as to facilitate the peeling of the photo-curable adhesive, and simplify steps and difficulties of the manufacturing.

The method for manufacturing the display panel provided by the present disclosure will be described in detail below through an embodiment.

First, materials to be manufactured are provided, the materials include a first substrate 1, a photo-curable adhesive 411, a light shielding layer 51, and a mother substrate 61 for a second-substrate.

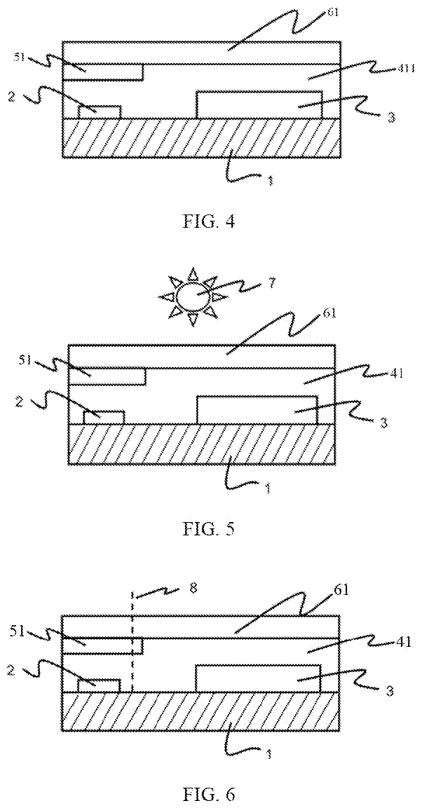

As shown in FIG. 4, the organic light-emitting device is arranged on the first substrate 1. The organic light-emitting device includes an electrode 2 and an organic light-emitting layer 3. The organic light-emitting layer 3 is used as a light-emitting part of the organic light-emitting device. The method for manufacturing the electrode 2 and the organic light-emitting layer 3 is similar to that in the related art, which will not be repeated here.

Next, as shown in FIG. 4, the electrode 2 and the organic light-emitting layer 3 are coated with a photo-curable adhesive 411, and the photo-curable adhesive 411 covers the first substrate 1. In some embodiments, the electrode 2 is a plurality of wires in a peripheral area of the display panel. For example, a plurality of signal lines are provided in the light-emitting area of the display panel, including but not limited to, gate scanning signal lines, data lines, reset control signal lines, light-emitting control signal lines, and the like. The wires (that is, the electrodes 2) located in the peripheral area of the display panel may be electrically coupled to these signal lines to lead out these signal lines, so that the electrodes may be electrically coupled to external circuits.

Next, the mother substrate 61 provided with the light shielding layer 51 is provided. As shown in FIG. 4, the mother substrate 61 provided with the light shielding layer 51 is adhered to the photo-curable adhesive 411, with the light shielding layer 51 facing the photo-curable adhesive 411. A position of the light shielding layer 51 corresponds to that of the electrode 2, and an area of the light shielding layer 51 is slightly larger than that of the electrode 2.

For example, in a cross-sectional direction of the mother substrate 61, a sidewall of the mother substrate 61 away from the organic light-emitting layer 3 coincides with a sidewall of the light shielding layer 51 away from the organic light-emitting layer 3, which is beneficial to the production process and improves the production efficiency.

Next, as shown in FIG. 5, the whole structure is placed in an environment with UV 7 for a period of time, so that the photo-curable adhesive 411 is cured to form the photo-curable adhesive material layer 41, thereby achieving the adhering of the first substrate 1 and the mother substrate 61 through the photo-curable adhesive material layer 41. During an irradiating process of the UV 7, due to the arrangement of the light shielding layer 51, a portion of the photo-curable adhesive material layer 41 under the light shielding layer 51 is not cured, and the light shielding layer 51 may well block the irradiation of the UV 7 to prevent the UV 7 from damaging the electrode 2.

Finally, as shown in FIG. 6, after the photo-curable adhesive material layer 41 is fully cured, a portion of the mother substrate 61 corresponding to the electrode 2 is cut off along a preset cutting line 8. After the portion of the mother substrate 61 is cut off, so as to form a second substrate 6. An uncured portion of the photo-curable adhesive material layer 41 disposed under the second substrate 6 is peeled off to expose the electrode 2, so that the electrode 2 may be coupled to other electrical components to achieve transmission of electrical signals, as shown in FIG. 1A, thereby achieving the production of the display panel. A position of the cutting line 8 in the embodiment of the present disclosure may be selected only if the electrode 2 is reserved.

For example, the cutting line 8 is perpendicular to the first substrate 1, and an orthographic projection of the cutting line 8 on the first substrate 1 is located between the electrode 2 and the organic light-emitting layer 3. In addition, the orthographic projection of the cutting line 8 on the first substrate 1 is located in the orthographic projection of the light shielding layer 51 on the first substrate 1. Alternatively, the orthographic projection of the cutting line 8 on the first substrate 1 is located outside the orthographic projection of the light shielding layer 51 on the first substrate. These two design methods may be applied to display panels with different requirements so as to enhance the market competitiveness.

For example, in a case that the orthographic projection of the cutting line 8 on the first substrate 1 is located in the orthographic projection of the light shielding layer 51 on the first substrate 1, a portion of the light shielding layer 51 remains after cutting, and the remaining portion of the light shielding layer 51 forms the light shielding structure 5. The position of the cutting line 8 may be as shown in FIG. 6, and a structure formed after cutting is shown in FIG. 1A.

For example, in a case that the orthographic projection of the cutting line 8 on the first substrate 1 is located outside the orthographic projection of the light shielding layer 51 on the first substrate 1, the light shielding layer 51 does not remain after cutting, and a structure formed after cutting is as shown in FIG. 2.

In the display panel provided by the present disclosure, the production of the organic light-emitting layer may be achieved by using one type of photo-curable adhesive. The usage of the photo-curable adhesive may increase an area of the curable area, which may improve a production effect, improve resistance to water and oxygen, and ensure a sufficient mechanical strength, thereby extending a service life of the organic light-emitting device. Moreover, the light shielding layer provided on the second substrate may shield the electrode during a manufacturing process. No additional shielding components are required, and the manufacturing structure is simpler. In addition, the electrode 2 is exposed, so that the electrode may be coupled with other electrical components without affect the manufacturing process, which enhances the market competitiveness. In a method for manufacturing the display panel provided by the present disclosure, the light shielding layer provided on a second substrate may shield the electrode 2 during the manufacturing process. No additional shielding components are required, and the process for manufacturing the display panel is simplified. Moreover, the production may be achieved by using one type of photo-curable adhesive, so that in the curing process, the photo-curable adhesive used may increase the area of the curable area, so as to improve the production effect, increase resistance to water and oxygen, and ensure a sufficient mechanical strength, thereby extending the service life of the organic light-emitting device. In addition, the electrode included in the organic light-emitting device is exposed, so that the electrode may be coupled to other electrical components without affecting the manufacturing process, which simplifies all the manufacturing steps, greatly improves the manufacturing efficiency, and enhances the market competitiveness.

The above are only part of the embodiments of the present disclosure. It should be noted that for those ordinary skilled in the art, without departing from the principles of the present disclosure, several improvements and modification may be made. These improvements and modification should also be regarded as the scope of protection of the present disclosure.

1. A display panel, comprising:
a first substrate;
an electrode arranged on the first substrate;
an organic light-emitting layer arranged on a side of the electrode away from the first substrate, wherein an orthographic projection of a cross section of the organic light-emitting layer on the first substrate does not overlap an orthographic projection of a cross section of the electrode on the first substrate;
a photo-curable adhesive layer covering the organic light-emitting layer;
a second substrate arranged on a side of the photo-curable adhesive layer away from the first substrate; and
a light shielding structure located on a side of the second substrate facing the first substrate and located in an edge area, wherein the edge area is located on a side of the second substrate facing the electrode; and
wherein an orthographic projection of a cross section of the light shielding structure on the first substrate does not overlap the orthographic projection of the cross section of the organic light-emitting layer on the first substrate.

2. The display panel according to claim 1, wherein an orthographic projection of a cross section of the photo-curable adhesive layer on the first substrate covers the orthographic projection of the cross section of the organic light-emitting layer on the first substrate.

3. The display panel according to claim 1, wherein each of orthographic projections of cross sections of the light shielding structure, the second substrate and the photo-curable adhesive layer on the first substrate does not overlap the orthographic projection of the cross section of the electrode on the first substrate.

4. The display panel according to claim 1, wherein the orthographic projection of the cross section of the light shielding structure on the first substrate is located between the orthographic projection of the cross section of the electrode on the first substrate and the orthographic projection of the cross section of the organic light-emitting layer on the first substrate.

5. The display panel according to claim 1, wherein the photo-curable adhesive layer is made of an epoxy acrylic resin material.

6. A display device, comprising a display panel, wherein the display panel comprises: a first substrate; an electrode arranged on the first substrate; an organic light-emitting layer arranged on a side of the electrode away from the first substrate, wherein an orthographic projection of a cross section of the organic light-emitting layer on the first substrate does not overlap an orthographic projection of a cross section of the electrode on the first substrate; a photo-curable adhesive layer covering the organic light-emitting layer; a second substrate arranged on a side of the photo-curable adhesive layer away from the first substrate; and a light shielding structure located on a side of the second substrate facing the first substrate and located in an edge area, wherein the edge area is located on a side of the second substrate facing the electrode; and wherein an orthographic projection of a cross section of the light shielding structure on the first substrate does not overlap the orthographic projection of the cross section of the organic light-emitting layer on the first substrate.

7. A method for manufacturing a display panel, comprising:
providing a first substrate, and arranging an electrode and an organic light-emitting layer on the first substrate;
coating the electrode and the organic light-emitting layer with a photo-curable adhesive, and covering the first substrate with the photo-curable adhesive;
providing a mother substrate for a second substrate, and arranging a light shielding layer on the mother substrate;
arranging the mother substrate with the light shielding layer on the photo-curable adhesive, with the light shielding layer facing the first substrate, wherein the light shielding layer is configured to shield light irradiated on the electrode, and an orthographic projection of a cross section of the light shielding layer on the first substrate does not overlap an orthographic projection of a cross section of the organic light-emitting layer on the first substrate;
performing a curing treatment on the photo-curable adhesive to form a photo-curable adhesive material layer, wherein the photo-curable adhesive material layer comprises an uncured portion;
cutting at a predetermined cutting position to cut off a portion of each of the mother substrate and the light shielding layer, so as to form the second substrate and a light shielding structure, respectively; and
peeling off the uncured portion of the photo-curable adhesive material layer to expose the electrode, wherein a remaining portion of the photo-curable adhesive material layer forms a photo-curable adhesive layer.

8. The method according to claim 7, wherein the performing a curing treatment on the photo-curable adhesive comprises performing an ultraviolet curing treatment on the photo-curable adhesive.

9. The method according to claim 7, wherein the arranging a light shielding layer on the mother substrate comprises depositing the light shielding layer on the mother substrate by a deposition process.

10. The method according to claim 9, wherein the light shielding layer is made of aluminum or titanium.

11. The method according to claim 7, wherein the orthographic projection of the cross section of the light shielding layer on the first substrate covers an orthographic projection of a cross section of the electrode on the first substrate.

12. The method according to claim 7, wherein an orthographic projection of a sidewall of the second substrate away from the organic light-emitting layer on the first substrate coincides with an orthographic projection of a sidewall of the light shielding layer away from the organic light-emitting layer on the first substrate in a cross-sectional direction of the second substrate.

13. The method according to claim 7, wherein the cutting at a predetermined cutting position comprises cutting between the electrode and the organic light-emitting layer, so that a distance between an orthographic projection of a cross section of the electrode on the first substrate and an orthographic projection of a cross section of the photo-curable adhesive layer on the first substrate is greater than 500 microns.

14. The display panel according to claim 1, wherein an orthographic projection of a cross section of the second substrate on the first substrate completely overlaps the orthographic projection of the cross section of the photo-curable adhesive layer on the first substrate.

15. The display panel according to claim 1, wherein a sidewall of the light shielding structure close to the electrode coincides with a sidewall of the photo-curable adhesive layer close to the electrode.

16. The display panel according to claim 1, wherein the first substrate is a thin film transistor substrate or a silicon substrate, and the second substrate is a metal substrate or a glass substrate.

17. The display device according to claim 6, wherein an orthographic projection of a cross section of the photo-curable adhesive layer on the first substrate covers the orthographic projection of the cross section of the organic light-emitting layer on the first substrate.

18. The display device according to claim 6, wherein an orthographic projection of a cross section of the second substrate on the first substrate completely overlaps the orthographic projection of the cross section of the photo-curable adhesive layer on the first substrate.

19. The display device according to claim 6, wherein each of orthographic projections of cross sections of the light shielding structure, the second substrate and the photo-curable adhesive layer on the first substrate does not overlap the orthographic projection of the cross section of the electrode on the first substrate.

20. The display device according to claim 6, wherein a sidewall of the light shielding structure close to the electrode coincides with a sidewall of the photo-curable adhesive layer close to the electrode.
